(19) United States
(12) Patent Application Publication
(10) Pub. No.: US 2025/0266116 A1
(43) Pub. Date: Aug. 21, 2025

(54) LOG LIKELIHOOD RATIO ESTIMATION BASED ON PREVIOUS STAGE OF ERROR HANDLING IN MEMORY DEVICES

(71) Applicant: Micron Technology, Inc., Boise, ID (US)

(72) Inventors: Phong Sy Nguyen, Livermore, CA (US); Sivagnanam Parthasarathy, Carlsbad, CA (US); Patrick R. Khayat, San Diego, CA (US)

(21) Appl. No.: 19/043,647

(22) Filed: Feb. 3, 2025

Related U.S. Application Data
(60) Provisional application No. 63/555,598, filed on Feb. 20, 2024.

(51) Int. Cl. G11C 29/12; G11C 29/42

(52) U.S. Cl. CPC G11C 29/12005; G11C 29/42

(57) ABSTRACT

A method of log likelihood ratio estimation includes: reading current stage data representing a subset of encoded data; determining, for each decoder input bin, a first number of memory cells having their respective threshold voltages falling into the decoder input bin and having a first binary value yielded by a previous stage of the read error handling sequence; determine, for each decoder input bin, a second number of memory cells having their respective threshold voltages falling into the decoder input bin and having a second binary value yielded by the previous stage; calibrating, for each decoder input bin, a corresponding likelihood value based on the first number of memory cells and the second number of memory cells; associating each memory cell with a respective likelihood value corresponding to a decoder input bin; and decoding, based on the likelihood values associated with the plurality of memory cells, the current stage data.

### REFERENCE TO RELATED APPLICATION

This application claims the priority benefit of U.S. Provisional Patent Application No. 63/555,598, filed Feb. 20, 2024, the entirety of which is incorporated herein by reference.

### TECHNICAL FIELD

Implementations of the disclosure relate generally to memory sub-systems, and more specifically, relate to log likelihood ratio estimation based on the output of previous read error handling stages.

### BACKGROUND

A memory sub-system may include one or more memory devices that store data. The memory devices may be, for example, non-volatile memory devices and volatile memory devices. In general, a host system may utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various implementations of the disclosure. The drawings, however, should not be taken to limit the disclosure to the specific implementations, but are for explanation and understanding only.

FIG. 1A illustrates an example computing system that includes a memory sub-system in accordance with aspects of the present disclosure.

FIG. 1B illustrates a block diagram of a memory device in communication with a memory sub-system in accordance with aspects of the present disclosure.

FIG. 2 schematically illustrates example of assigning sensed data values to respective decoder input bins, in accordance with aspects of the present disclosure.

FIG. 3 schematically illustrates the process of calibrating log likelihood ratio (LLR) mapping tables based on the decoder output produced at the previous read error handling stage, in accordance with aspects of the present disclosure.

FIG. 4 is a high-level flow diagram of an example method of estimating the log likelihood ratios based on a previous stage of an error handling sequence in a memory device, in accordance with aspects of the present disclosure.

FIG. 5 is a block diagram of an example computer system in which implementations of the present disclosure may operate.

### DETAILED DESCRIPTION

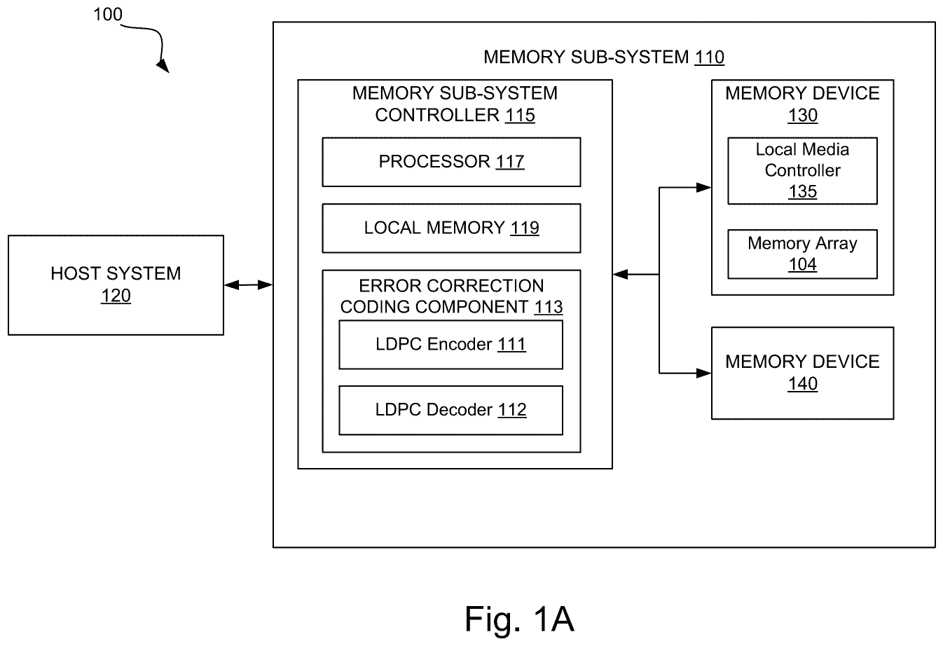

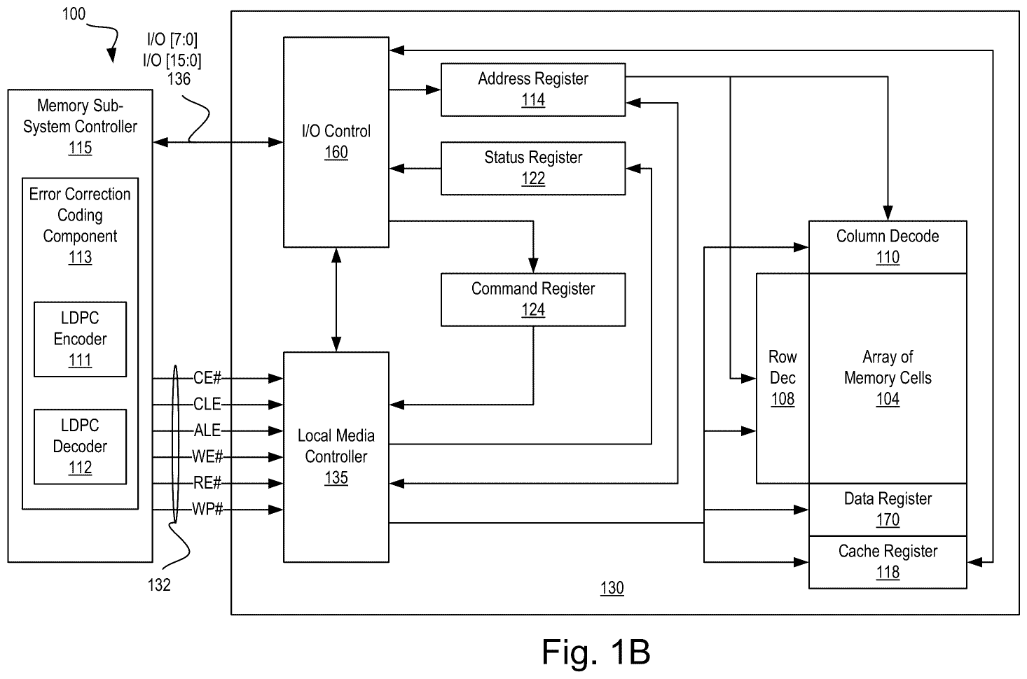

Aspects of the present disclosure are related to log likelihood ratio estimation based on the output of one or more previous read error handling stage in memory sub-systems. A memory sub-system may be a storage device, a memory module, or a combination of a storage device and memory module. Examples of storage devices and memory modules are described below in conjunction with FIG. 1. In general, a host system may utilize a memory sub-system that includes one or more components, such as memory devices that store data. The host system may provide data to be stored at the memory sub-system and may request data to be retrieved from the memory sub-system.

A memory sub-system may utilize one or more memory devices, including any combination of the different types of non-volatile memory devices and/or volatile memory devices, to store the data provided by the host system. In some implementations, a memory sub-system may be represented by a solid-state drive (SSD), which may include one or more non-volatile memory devices. In some implementations, the non-volatile memory devices may be provided by negative-and (NAND) type flash memory devices. Other examples of non-volatile memory devices are described below in conjunction with FIG. 1. A non-volatile memory device is a package of one or more dice. Each die may include one or more planes. A plane is a portion of a memory device that includes multiple memory cells. Some memory devices may include two or more planes. For some types of non-volatile memory devices (e.g., NAND devices), each plane includes a set of physical blocks. Each block includes a set of pages. “Block” herein shall refer to a set of contiguous or non-contiguous memory pages. A “block” may refer to a unit of the memory device used to store data and may include a group of memory cells. An example of a “block” is an “erasable block,” which is the minimal erasable unit of memory, while “page” is a minimal writable unit of memory. Each page includes a set of memory cells. A memory cell is an electronic circuit that stores information.

A memory device may include multiple memory cells arranged in a two-dimensional grid. The memory cells are formed onto a silicon wafer in an array of columns and rows. A memory cell includes a capacitor that holds an electric charge and a transistor that acts as a switch controlling access to the capacitor. Accordingly, the memory cell may be programmed (written to) by applying a certain voltage, which results in an electric charge being held by the capacitor. The memory cells are joined by wordlines, which are conducting lines electrically connected to the control gates of the memory cells, and bitlines, which are conducting lines electrically connected to the drain electrodes of the memory cells.

Depending on the cell type, each memory cell may store one or more bits of binary information and has various logic states that correlate to the number of bits being stored. The logic states may be represented by binary values, such as “0” and “1”, or combinations of such values. A memory cell may be programmed (written to) by applying a certain voltage to the memory cell, which results in an electric charge being held by the memory cell, thus allowing modulation of the voltage distributions produced by the memory cell. A set of memory cells referred to as a memory page may be programmed together in a single operation, e.g., by selecting consecutive bitlines.

Precisely controlling the amount of the electric charge stored by the memory cell allows establishing multiple logical levels, thus effectively allowing a single memory cell to store multiple bits of information. A read operation may be performed by comparing the measured threshold voltages (Vt) exhibited by the memory cell to one or more reference voltage levels in order to distinguish between two logical levels for single-level cell (SLCs) and between multiple logical levels for multi-level cells. Each logical level may be translated into a corresponding binary representation of the content of the memory cell. In an illustrative example, a Gray code may be employed for translating the cell charge levels (voltage levels) into their respective binary representations and vice versa. A Gray code refers to an encoding in which adjacent numbers have a single digit different by one.

Memory access operations (e.g., a read operation, a programming (write) operation, an erase operation, etc.) may be executed with respect to sets of the memory cells, e.g., in response to receiving memory access commands from the host. A memory access operation may specify the requested memory access operation (e.g., write, erase, read, etc.) and a logical address, which the memory sub-system would translate to a physical address identifying a set of memory cells (e.g., a block).

In order to improve endurance of a memory device, the data to be written to the memory device may be modulated to achieve a desired distribution of the charge levels in the memory cells addressable by a given wordline and, in some implementations, also in the memory cells addressable by neighboring wordlines of the given wordline. For example, a random data pattern encoded by a Gray code would result in uniform distribution of the memory cell charge levels (such that the number of memory cells at an arbitrary chosen charge level being roughly equal to the number of memory cells at any other charge level).

The modulated data may be encoded prior to being stored on a memory device, and thus would need to be decoded when later retrieved from the memory sub-system. For example, a sequence of symbols (e.g., representing one or more bits of binary information), may be transformed by an encoder to generate a codeword, which may then be stored on a memory device. However, in some cases, the sensed data read back from the memory device may differ from the original encoded data, e.g., on account of errors (e.g., bit-flip errors) that may have occurred during storage and/or retrieval of the encoded data to/from the memory device.

In some implementations, the data may be encoded using an error correcting code (ECC), which produces encoded data that includes redundant information allowing the original data to be recovered even if some errors have been introduced during the data storage and/or retrieval. Accordingly, the transformation employed by the encoder may be chosen such that the errors (e.g., bit flips that may occur when storing and/or retrieving the codeword) may be detected and corrected when the codeword is later retrieved from the memory device thereof.

One class of ECCs that may be used are linear codes, which may be characterized by a set of linearly independent relationships. For example, a linear code having codewords of length N, that may carry K information symbols and (N−K) (or M) parity-check symbols, in general, may be characterized by (N−K) linear relationships. Linear codes may be defined by a parity-check matrix, which may describe the linear relationships that elements of a valid codeword must satisfy. Each row of a parity-check matrix, for example, may describe a separate linear relationship that a valid codeword must satisfy (e.g., requiring the weighted sum of specific elements of the codeword to equal zero), with the value in each column indicating a weight that a particular element is given in the relationship. For instance, each row of a parity-check matrix that defines a binary linear code may require the modulo-2 sum of specific bits of a codeword, which may be given a column weight of ‘1’ (and all other bits ‘0’), to be equal to zero.

Low density parity check (LDPC) codes are a family of linear codes having sparsely populated parity-check matrices (e.g., having a low density of non-zero symbols). A binary LDPC code having codewords of length N, comprising K bits of information and M parity-check bits, may be defined by a parity-check matrix of size M×N. Similarly, a non-binary LDPC code, in which each symbol of the non-binary alphabet represents s bits, may be defined by a parity-check matrix of size sM×sN.

A parity-check matrix having M rows and N columns may define an LDPC code having codewords of length N that may carry K information bits and M parity bits. Each row of the parity-check matrix may describe a linear relationship that a valid codeword of the LDPC code must satisfy. For example, a row of the parity-check matrix may require a valid codeword to satisfy the relationship: bit-2 ⊕ bit-6 ⊕ bit-7 ⊕ . . . ⊕ bit-N−4−=0.

Data encoded using an LDPC code may be decoded using different techniques, which may vary in terms of the input they take and the error correction capabilities they provide. Hard-decision decoding techniques, for example, may rely on a “hard” input value of a received codeword (e.g., a singular determination as to whether each bit-value of a codeword is ‘0’ or ‘1’). A memory sub-system, for example, in retrieving a stored codeword from a memory device, may perform a read operation that makes a hard decision as to the value of each bit of the codeword (i.e., as being either ‘0’ or ‘1’) and returns a series of “hard bits.”

Should the decoder fail to correct one or more errors in the sensed data, the memory sub-system may perform a read error handling sequence in an attempt to recover the data. The read error handling sequence may include one or more read error handling operations. An error handling operation, for example, may include one or more read retries using different parameters, such as the read voltage, as compared to the previous read operation performed on the memory cell. In some implementations, read voltage level adjustments may be performed based on values of one or more data state metrics obtained from a sequence of read and/or write operations. In an illustrative example, the data state metric may be represented by a raw bit error rate (RBER), which refers to the error rate in terms of a measure of bits that contain incorrect data (i.e., bits that were sensed erroneously) when a data access operation is performed on a memory device (e.g., the ratio of the number of erroneous bits to the number of all data bits stored in a certain portion, such as a specified block, of the memory device).

In some implementations, upon failing to successfully decode the sensed data based on the hard bits, the memory sub-system may employ a soft-decision decoding techniques, which may take into account “soft” input information (alongside a hard input value) indicating the reliability of a hard value determination (e.g., a confidence level or likelihood that a particular bit-value is in fact ‘0’ or ‘1’). Thus, a memory sub-system, in retrieving a stored codeword, may perform a read operation that not only returns a hard value as a series of hard bits, but also a series of one or more “soft bits” for each hard bit, which may indicate a reliability of a particular hard bit determination.

A read operation may measure the threshold voltage of a target memory cell of a set of memory cells. By comparing the measured threshold voltage value to the estimated threshold voltage distributions associated with the set of memory cells, the read operation may return a predefined number of “soft bits” of information for each “hard” bit. Soft-decision decoding techniques may be described in terms of the number of hard bits (H) and soft bits(S) that are provided as input to the decoder (e.g., 1H2S, 1H3S, etc.).

In general, soft-decision decoding techniques may provide for relatively better error correction as compared to hard-decision decoding techniques, but they tend to be more expensive to implement. Soft-decision decoding techniques, for example, may involve more complicated and time-consuming read operations (e.g., to obtain the desired reliability information), utilize higher power and/or more complex decoding circuitry, or present other issues.

In an illustrative example, a memory sub-system may perform a read operation that returns an estimated threshold voltage value for a particular memory cell. The voltage value may fall within one of a predefined plurality of decoder input bins. Each decoder input bin may be associated with a predefined sequence of bit values, including one hard bit value and one or more soft bit values. For example, the memory sub-system may perform a read operation that returns three soft bits of information for each hard bit, with ‘000’ indicating the lowest level of reliability and ‘111’ indicating the highest level of reliability in the hard bit determination.

The combination of the hard bit and the soft bits may be converted into a likelihood value, which reflects the probability that the memory cell will be decoded as a specific binary value (e.g., “1”). In other words, the combination of the hard bit and one or more corresponding soft bits may be translated into a likelihood value that reflects the probability of the memory cell (having its threshold voltage within a decoder input bin that is identified by the combination of the hard bit and the corresponding soft bits) to be decoded as a particular binary value (e.g., “1”).

In some implementations, the likelihood value may be represented by the log likelihood ratio:

$$LLR ( bit i ) = log ( \frac{P ( bit i = 0 \vert read info}{P ( bit i = 1 \vert read info} )$$

where i is the identifier of the bit (the memory cell for SLC),
read info is the information read from the memory device (i.e., the combination of the hard bit and its corresponding soft bits),
P(bit i=0|read info) is the probability of bit i be decoded as 0 based on the information read from the memory device (i.e., the combination of the hard bit and its corresponding soft bits), and
P(bit i=1|read info) is the probability of bit i be decoded as 1 based on the information read from the memory device (i.e., the combination of the hard bit and its corresponding soft bits).

In some implementations, converting the combination of the hard bit and the soft bits into a corresponding LLR value may be performed using a look-up table (LUT), which may map various possible combinations of the hard bit and soft bits into corresponding LLR values. The LUT may be pre-computed by the manufacturer of the memory sub-system and stored in the metadata area of a memory device. The memory sub-system may then provide the LLR values corresponding to the sensed data returned by a read operation to an LDPC decoder, which may attempt to decode the sensed data.

However, the accuracy of the resulting LLR values may vary per from codeword to codeword due to several reasons, including suboptimal read levels, level-to-level variability of the threshold voltage distributions, and/or asymmetric shapes of the threshold voltage distributions. Thus, using the precomputed LLR mapping tables may result in inaccurate LLR estimates.

Accordingly, aspects of the present disclosure improve the efficiency of memory access operations by dynamically adjusting (calibrating) the LLR mapping tables based on the decoder output produced at the previous read error handling stage. Such adaptive calibration of the LLR mapping tables may improve the CWER (Codeword Error Rate) of LDPC, thus resulting in better Trigger Rate (TR), Quality of Service (QOS) and/or reliability of the memory device.

Various aspects of the methods and systems are described herein by way of examples, rather than by way of limitation. The systems and methods described herein may be implemented by hardware (e.g., general purpose and/or specialized processing devices, and/or other devices and associated circuitry), software (e.g., instructions executable by a processing device), or a combination thereof.

FIG. 1 illustrates an example computing system 100 that includes a memory sub-system 110 in accordance with some implementations of the present disclosure. The memory sub-system 110 may include media, such as one or more volatile memory devices (e.g., memory device 140), one or more non-volatile memory devices (e.g., memory device 130), or a combination of such.

A memory sub-system 110 may be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 may be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 may include a host system 120 that is coupled to one or more memory sub-systems 110. In some implementations, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which may be an indirect communicative connection or direct communicative connection (e.g., without intervening components), whether wired or wireless, including connections such as electrical, optical, magnetic, etc.

The host system 120 may include a processor chipset and a software stack executed by the processor chipset. The processor chipset may include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 may be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface may be used to transmit data between the host system 120 and the memory sub-system 110. The host system 120 may further utilize an NVM Express (NVMe) interface to access components (e.g., memory devices 130) when the memory sub-system 110 is coupled with the host system 120 by the physical host interface (e.g., PCIe bus). The physical host interface may provide an interface for passing control, address, data, and other signals between the memory sub-system 110 and the host system 120. FIG. 1 illustrates a memory sub-system 110 as an example. In general, the host system 120 may access multiple memory sub-systems via a same communication connection, multiple separate communication connections, and/or a combination of communication connections.

The memory devices 130, 140 may include any combination of the different types of non-volatile memory devices and/or volatile memory devices. The volatile memory devices (e.g., memory device 140) may be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells may perform bit storage based on a change of bulk resistance, in conjunction with a stackable cross-gridded data access array. Additionally, in contrast to many flash-based memories, cross-point non-volatile memory may perform a write in-place operation, where a non-volatile memory cell may be programmed without the non-volatile memory cell being previously erased. NAND type flash memory includes, for example, two-dimensional NAND (2D NAND) and three-dimensional NAND (3D NAND).

Each of the memory devices 130 may include one or more arrays of memory cells. One type of memory cell, for example, single level cells (SLC) may store one bit per cell. Other types of memory cells, such as multi-level cells (MLCs), triple level cells (TLCs), quad-level cells (QLCs), and penta-level cells (PLCs) may store multiple bits per cell. In some implementations, each of the memory devices 130 may include one or more arrays of memory cells such as SLCs, MLCs, TLCs, QLCs, PLCs or any combination of such. In some implementations, a particular memory device may include an SLC portion, and an MLC portion, a TLC portion, a QLC portion, or a PLC portion of memory cells. The memory cells of the memory devices 130 may be grouped as pages that may refer to a logical unit of the memory device used to store data. With some types of memory (e.g., NAND), pages may be grouped to form blocks.

Although non-volatile memory components such as a 3D cross-point array of non-volatile memory cells and NAND type flash memory (e.g., 2D NAND, 3D NAND) are described, the memory device 130 may be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) may communicate with the memory devices 130 to perform operations such as reading data, writing data, or erasing data at the memory devices 130 and other such operations. The memory sub-system controller 115 may include hardware such as one or more integrated circuits and/or discrete components, a buffer memory, or a combination thereof. The hardware may include a digital circuitry with dedicated (i.e., hard-coded) logic to perform the operations described herein. The memory sub-system controller 115 may be a microcontroller, special purpose logic circuitry (e.g., a field programmable gate array (FPGA), an application specific integrated circuit (ASIC), etc.), or other suitable processor.

The memory sub-system controller 115 may include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some implementations, the local memory 119 may include memory registers storing memory pointers, fetched data, etc. The local memory 119 may also include read-only memory (ROM) for storing micro-code. While the example memory sub-system 110 in FIG. 1 has been illustrated as including the memory sub-system controller 115, in another implementation of the present disclosure, a memory sub-system 110 does not include a memory sub-system controller 115, and may instead rely upon external control (e.g., provided by an external host, or by a processor or controller separate from the memory sub-system).

In general, the memory sub-system controller 115 may receive commands or operations from the host system 120 and may convert the commands or operations into instructions or appropriate commands to achieve the desired access to the memory devices 130. The memory sub-system controller 115 may be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115, for example, may employ a Flash Translation Layer (FTL) to translate logical addresses to corresponding physical memory addresses, which may be stored in one or more FTL mapping tables. In some instances, the FTL mapping table may be referred to as a logical-to-physical (L2P) mapping table storing L2P mapping information. The memory sub-system controller 115 may further include host interface circuitry to communicate with the host system 120 via the physical host interface. The host interface circuitry may convert the commands received from the host system into command instructions to access the memory devices 130 as well as convert responses associated with the memory devices 130 into information for the host system 120.

The memory sub-system 110 may also include additional circuitry or components that are not illustrated. In some implementations, the memory sub-system 110 may include a cache or buffer (e.g., DRAM) and address circuitry (e.g., a row decoder and a column decoder) that may receive an address from the memory sub-system controller 115 and decode the address to access the memory devices 130.

In some implementations, the memory devices 130 include local media controllers 135 that operate in conjunction with memory sub-system controller 115 to execute operations on one or more memory cells of the memory devices 130. An external controller (e.g., memory sub-system controller 115) may externally manage the memory device 130 (e.g., perform media management operations on the memory device 130). In some implementations, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

As noted above, memory sub-system 110 may include an error correction coding component 113 that may be used to encode data for storage on a memory device and decode encoded data when retrieved from a memory device. In some implementations, memory sub-system 110 (e.g., memory sub-system control 115) may receive data from host system 120 along with a command to store the host data. The host data received from host system 120 may be or include a stream of one or more data symbols (e.g., representing one or more bits of binary information). In some cases, for example, the host data may be or include a stream of binary data bits (e.g., a stream of 0's and 1's). Memory sub-system 110 (e.g., memory sub-system controller 115) may provide the host data to error correction coding component 113 and instruct error correction coding component 113 to generate encoded host data (or encoded data) therefrom.

In some implementations, error correction coding component 113 may use an error correcting code (ECC), such as a low-density parity-check (LDPC) code, to encode data in such a way (e.g., by including redundant information) so as to allow errors, which may be introduced (e.g., during storage and/or retrieval of the encoded data to/from a memory device), to be detected and corrected when later decoded. In some implementations, error correction coding component 113 may include an LDPC encoder 111 that error correction coding component 113 may use to encode host data using an LDPC code. In some implementations, error correction coding component 113 may process host data using an LDPC code and generate one or more codewords therefrom. Error correction coding component 113, for instance, may use the LDPC encoder 111 to process a sequence of one or more symbols of host data and generate a codeword therefrom. Error correction coding component 113, for example, may use the LDPC encoder 111 to process K bits of host data to generate codewords of length N therefrom, which may contain K bits of host data and N−K (or M) bits of redundancy data (or parity-check bits).

In some implementations, error correction coding component 113 may provide LDPC encoder 111 with the host data and instruct the LDPC encoder 111 to encode the host data using an LDPC code. In some implementations, LDPC encoder 111 may use a parity-check matrix that defines an LDPC code (“LDPC matrix”) to encode host data (e.g., a host data sequence). The LDPC matrix be pre-computed by the manufacturer of the memory sub-system and stored in the metadata area of a memory device. For example, a binary LDPC code may be defined by a parity-check matrix H of size M×N. The LDPC encoder 111 may use parity-check matrix H to process K bits (or N−M bits) of host data to generate a codeword C of length N. In some implementations, the LDPC encoder 111 may derive a generator matrix G from the parity-check matrix H, which the LDPC encoder 111 may use to generate codeword C. The LDPC encoder 111, for instance, may multiply the K-bit host data sequence by generator matrix G to generate codeword C. In some implementations, a size of parity matrix H and/or value of K may be chosen so that the resulting codeword C is a particular size. The size of parity matrix H and/or value of K, for example, may be selected such that the codeword C generated therefrom is the same size as a page or block (or other grouping) of memory cells, which may facilitate storage of the encoded data on a memory device.

The encoded data generated by error correction coding component 113 may be returned to memory sub-system 110 (e.g., to memory sub-system controller 115), which may store the encoded data on a memory device 130. In some implementations, memory sub-system 110 may perform a write operation to write the encoded data (e.g., to write a generated codeword) to a memory device (e.g., at an identified storage location therein). In some implementations, encoded data may be returned to memory sub-system 110 and written to a memory device as the encoded data is generated (e.g., as each encoded codeword is generated). In some implementations, the encoded data may be returned to and/or written by memory sub-system 110 after all host data in a host data storage request has been encoded.

As noted above, ECC component 113 may also be used to decode encoded data when retrieved from a memory device. For example, in some implementations, memory sub-system 110 (e.g., memory sub-system controller 115) may receive a request from host system 120 to retrieve host data that was previously encoded and stored at memory sub-system 110 (e.g., in response to an earlier storage request). In response to the request, memory sub-system 110 may determine where encoded data corresponding to the requested host data is stored (e.g., using an FTL mapping table maintained by memory sub-system 110) and may perform a read operation to read the encoded data back from a memory device. In some implementations, memory sub-system 110 may read encoded data back from memory device 130 as part of a read operation by performing one or more sense operations to determine a value of the memory cells that store the encoded data. The encoded data read back from the memory device (or sensed data) may comprise one or more sensed codewords.

Memory sub-system 110 may provide the sensed data returned by a read operation to ECC component 113 and instruct ECC component 113 to decode the sensed data and obtain the host data encoded therein. In some instances, the sensed data read back from the memory device may differ from the initial encoded data that was first generated, for example, on account of errors (e.g., bit-flip errors) that may have occurred during storage and/or retrieval of the encoded data to/from the memory device. The sensed data, however, may be encoded using an ECC, such as an LDPC code, which may allow ECC component 113 to detect and correct errors in the sensed data and restore initial host data encoded therein.

In some implementations, ECC component 113 may include an LDPC decoder 112 that ECC component 113 may use to decode sensed data encoded using an LDPC code. In some implementations, ECC component 113 may use LDPC decoder 112 to process sensed data and obtain one or more sequences of host data encoded therein. In processing the sensed data, LDPC decoder 112 may detect and attempt to correct any errors therein. In some implementations, LDPC decoder 112 may use the LDPC matrix that defines an LDPC code to attempt to decode sensed data (e.g., to decode each sensed codeword).

In some implementations, memory sub-system 110 may employ multiple decoding techniques in order to achieve better overall performance. In some implementations, memory sub-system 110 may attempt to decode a codeword using a first technique (e.g., a hard-decision decoding technique), which may be performed relatively quickly and/or efficiently, and if it fails, a second fallback technique may be triggered (e.g., a soft-decision decoding technique), which may provide for more robust error correction. For example, in some implementations, memory sub-system 110 may perform a first read operation that may return sensed data in the form of hard codeword values, which may be provided to ECC component 113 for decoding. ECC component 113 may use LDPC decoder 112 to attempt to decode each codeword in the sensed data using a hard-decision decoding technique to obtain host data sequences therefrom (e.g., to obtain a host data sequence for each codeword in the sensed data). If LDPC decoder 112 is unable to successfully decode a sensed codeword (e.g., if LDPC decoder 112 is unable to correct all errors in the sensed codeword), an error handling procedure may be invoked that may perform a second read operation employing a soft-decision decoding techniques, which may take into account “soft” input information (alongside a hard input value) indicating the reliability of a hard value determination (e.g., a confidence level or likelihood that a particular bit-value is in fact ‘0’ or ‘1’). Thus, a memory sub-system, in retrieving a stored codeword, may perform a read operation that not only returns a hard value as a series of hard bits, but also a series of one or more “soft bits” for each hard bit, which may indicate a reliability of a particular hard bit determination (e.g., in the form of LLR values which are indicative of likelihood that a particular bit-value is in fact ‘0’ or ‘1’).

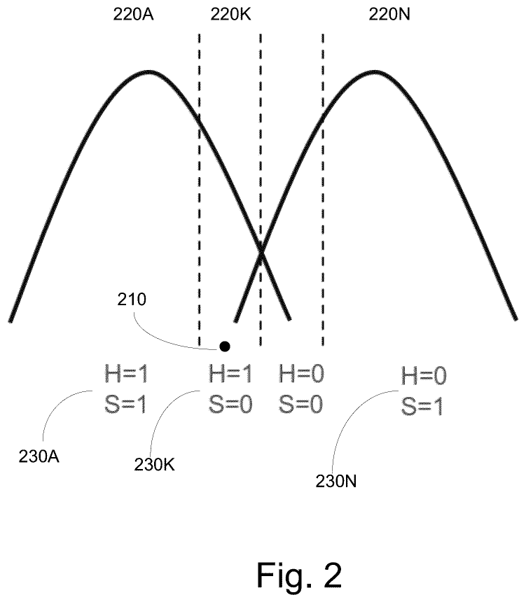

As schematically illustrated by FIG. 2, a memory sub-system may perform a read operation that returns an estimated threshold voltage value 210 for a particular memory cell. The voltage value 210 may fall within a decoder input bin 220K of a predefined plurality of decoder input bins 220A-220N. Each decoder input bin 220A-220N may be associated with a corresponding predefined sequence of bit values 230A-230N, including one hard bit value and one or more soft bit values. In the illustrative example of FIG. 2, the read operation returns one soft bit of information for each hard bit, with ‘0’ indicating the highest level of reliability and ‘1’ indicating the lowest level of reliability in the hard bit determination.

In general, a read operation that may return n soft bits of information for each hard bit, with ‘0 . . . 0’ indicating the lowest level of reliability and ‘1 . . . 1’ indicating the highest level of reliability in the hard bit determination. The number of decoder input bins would thus be determined by the number of soft bits of information returned by read operations:

$$N = {2}^{n + 1}$$

where N is the number of decoder input bins, and
n is the number of soft bits returned by read operations.

Each combination 230A-230N of the hard bit and the soft bits may be converted into a corresponding likelihood value, which reflects the probability that the memory cell will be decoded as a specific binary value (e.g., “1”). In other words, the combination of the hard bit and one or more corresponding soft bits may be translated into a likelihood value that reflects the probability of the memory cell (having its threshold voltage within a decoder input bin that is identified by the combination of the hard bit and the corresponding soft bits) to be decoded as a particular binary value (e.g., “1”).

In some implementations, the likelihood value may be represented by the log likelihood ratio:

$$LLR ( bit i ) = log ( \frac{P ( bit i = 0 \vert read info}{P ( bit i = 1 \vert read info} )$$

where i is the identifier of the bit (the memory cell for SLC),
read info is the information read from the memory device (i.e., the combination of the hard bit and its corresponding soft bits),
P(bit i=0|read info) is the probability of bit i be decoded as 0 based on the information read from the memory device (i.e., the combination of the hard bit and its corresponding soft bits), and
P(bit i=1|read info) is the probability of bit i be decoded as 1 based on the information read from the memory device (i.e., the combination of the hard bit and its corresponding soft bits).

In some implementations, converting the combination of the hard bit and the soft bits into a corresponding LLR value may be performed using a look-up table (LUT) 240, which may map various possible combinations 230A-230N of the hard bit and soft bits into corresponding LLR values. The memory sub-system may then provide the LLR values corresponding to the sensed data returned by a read operation to LDPC decoder 112, which may attempt to decode the sensed data.

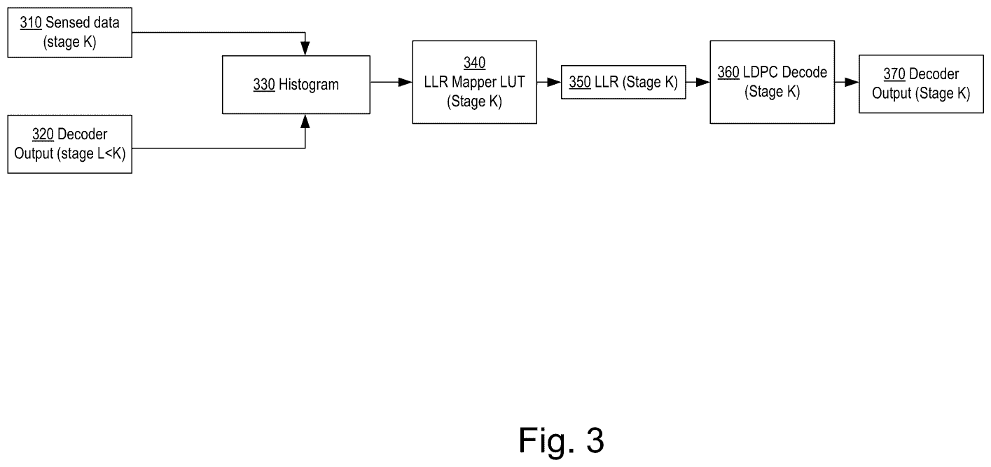

In some implementations, the LUT may be dynamically calibrated based on the decoder output produced at a previous read error handling stage. As schematically illustrated by FIG. 3, at stage K of the read error handling sequence, the histogram 330 is computed, which reflects the distribution of the current stage (stage K) sensed data 310 over the values of the decoder output 320 of a previous stage L<K of the error handling sequence. In an illustrative example, stage L may be the immediate previous stage with respect to the current stage K (i.e., L=K−1). In another illustrative example, stage L may be a previous stage (i.e., L<K) that produced the smallest syndrome weight among all previous stages of the error handling sequence.

“Syndrome” herein refers to the product of the parity check matrix and the decoded word (under the used finite field, typically binary). “Syndrome weight” refers to the number of non-zero symbols in the syndrome. Thus, the syndrome weight is positively correlated with the number of errors in the decoded word: a high syndrome weight is indicative of a high number of errors.

Generating the histogram 330 may involve counting, in the data sensed at stage K, the number of memory locations (e.g., memory cells) falling into each decoder input bin, conditioned on the value of the decoder output bit at that location at a previous Stage L<K:
C(j|0) denotes the number, in the data sensed at stage K, of memory locations having their respective threshold voltages falling into bin j conditioned on the decoder output at a previous stage L<K for such a memory location being equal to 0 (in other words, the number of memory locations for which the decoder output at stage L<K was 0 and which have having their respective threshold voltages falling into bin j at stage K); and
C(j|1) denotes the number, in the data sensed at stage K, of memory locations having their respective threshold voltages falling into bin j conditioned on the decoder output at a previous stage L<K for such a memory location being equal to 1 (in other words, the number of memory locations for which the decoder output at stage L<K was 1 and which have having their respective threshold voltages falling into bin j at stage K).

In some implementations, the conditional counts C(j|0) and C(j|1) may be normalized, e.g. by dividing each count value by the sum of the count values across all decoder output bins.

The conditional counts may then be utilized for calibrating the log likelihood ratio (LLR) values for each bin j at stage K:

$$LLR ( bin j ) = log ( \frac{C ( j \vert 0 )}{C ( j \vert 1 )} )$$

In some implementations, the LLR values may be further scaled and quantized using a chosen scale factor and a quantization function such as round, ceil, or floor:

$$LLR ( bin j ) = quantize ( scale * log ( \frac{C ( j \vert 0 )}{C ( j \vert 1 )} ) )$$

As noted herein above, each LLR value corresponding to a particular bin reflects the probability of a memory cell having its threshold voltage within the particular bin to be decoded as a particular binary value.

The computed LLR values may then be fed to the decoder for performing stage K decoding. Responsive to determining that the codeword produced by decoding the current stage data is error-free, the decoded may be returned to the host. Conversely, should the codeword comprises one or more errors, the next stage of the read error handling sequence may be initiated.

As noted herein above, the next stage may be performed using different parameters, such as the read voltage, as compared to the previous stage. In some implementations, read voltage level adjustments may be performed based on values of one or more data state metrics (e.g., RBER) obtained from a sequence of read and/or write operations.

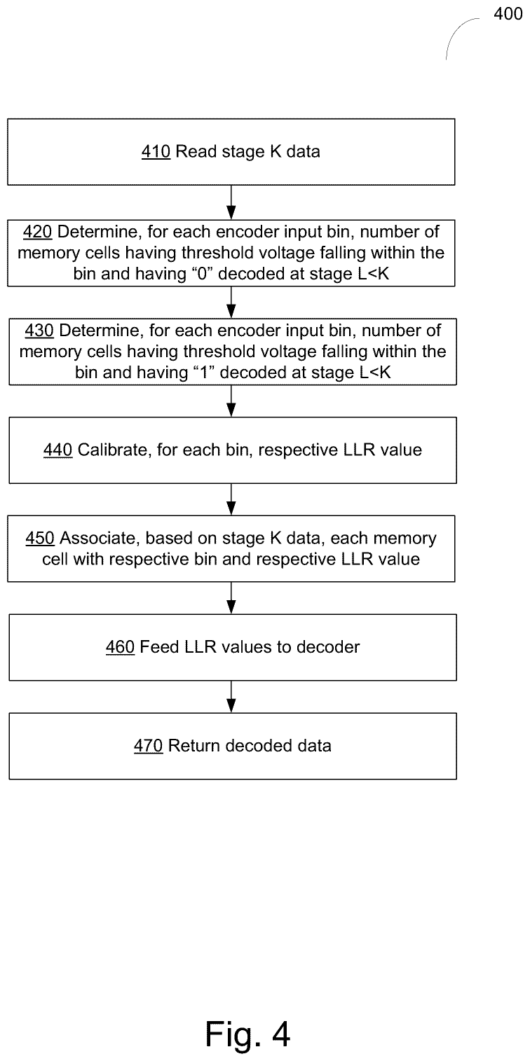

FIG. 4 is a high-level flow diagram of an example method 400 of estimating the log likelihood ratios based on a previous stage of an error handling sequence in a memory device, in accordance with aspects of the present disclosure. The method 400 can be performed by processing logic that can include hardware (e.g., general purpose or specialized processing devices, circuitry, dedicated logic, programmable logic, microcode, integrated circuits, etc.), software (e.g., instructions run or executed on a processing device), or various combinations thereof. In some implementations, method 400 can be performed by a single processing thread. Alternatively, method 400 can be performed by two or more processing threads, each thread executing one or more individual functions, routines, subroutines, or operations of the method. In an illustrative example, the processing threads implementing method 400 can be synchronized (e.g., using semaphores, critical sections, and/or other thread synchronization mechanisms). Alternatively, the processing threads implementing method 400 can be executed asynchronously with respect to each other. In some implementations, the method 400 is performed by the memory system controller (e.g., ECC component 113 of FIG. 1) and/or local media controller. Operations of the method 400 can be specified by a sequence of command codes, which the processing logic can retrieve from a dedicated storage location. Although shown in a particular sequence or order, unless otherwise specified, the order of the operations can be modified. Thus, the illustrated implementations should be understood only as examples, and the illustrated operations can be performed in a different order, and some operations can be performed in parallel. Additionally, one or more operations can be omitted in various implementations. Thus, not all operations are required in every implementation.

At operation 410, the processing logic may initiate a current stage (stage K>1) of an error handling sequence by retrieving encoded data from a memory device as sensed data. As noted herein above, the read error handling sequence may include one or more read error handling operations. An error handling operation may include one or more read retries using different parameters, such as the read voltage, as compared to the previous read operation performed on the memory cell. In some implementations, read voltage level adjustments may be performed based on values of one or more data state metrics (e.g., RBER) obtained from a sequence of read and/or write operations.

In some implementations, the processing logic may read encoded data from the memory device as part of a read operation by performing one or more sense operations to determine threshold voltage values of the memory cells that store the encoded data. The encoded data read back from the memory device (or sensed data) may comprise one or more sensed codewords. In some instances, the sensed data read back from the memory device may differ from the initial encoded data that was first generated, for example, on account of errors (e.g., bit-flip errors) that may have occurred during storage and/or retrieval of the encoded data to/from the memory device. The sensed data, however, may be encoded using an ECC, such as an LDPC code, which may allow the processing logic to detect and correct errors in the sensed data and obtain initial host data encoded therein.

At operations 420-440, the processing logic may calibrate the LLR mapping tables based on the decoder output produced at a chosen previous read error handling stage (stage L<K). In some implementations, the calibration is only performed if the syndrome weight produced by the previous error handling stage falls below a threshold syndrome weight value; otherwise, the decoded output may contain too many errors and may not be used as a representative proxy of the data stored on the memory device. Accordingly, should the syndrome weight produced by the previous error handling stage exceed threshold syndrome weight value, the precomputed LUTs may be utilized for computing the LLR values.

In some implementations, stage L may be the immediate previous stage with respect to the current stage K (i.e., L=K−1). Alternatively, stage L may be a previous stage (i.e., L<K) that produced the smallest syndrome weight among all previous stages of the error handling sequence.

Thus, at operation 420, the processing logic may determine, for each decoder input bin of a chosen set of decoder input bins, the number of memory cells having their respective threshold voltages falling into the decoder input bin and further having the binary value of “0” yielded by the previous stage of the read error handling sequence.

At operation 430, the processing logic may determine, for each decoder input bin of a chosen set of decoder input bins, the number of memory cells having their respective threshold voltages falling into the decoder input bin and further having the binary value of “1” yielded by the previous stage of the read error handling sequence.

At operation 440, the processing logic may calibrate, for each decoder input bin of a plurality of decoder input bins, a corresponding likelihood value based on the numbers of memory cells computed at operations 420-430.

In an illustrative example, the likelihood value associated with a decoder input bin may be represented by the logarithm of the ratio of the first number of memory cells having the first binary value yielded by the previous stage of the read error handling sequence and the second number of memory cells having the second binary value yielded by the previous stage of the read error handling sequence:

$$LLR ( bin j ) = log ( \frac{C ( j \vert 0 )}{C ( j \vert 1 )} )$$

as described in more detail herein above.

At operation 450, the processing logic may associate, based on the sensed data of the current stage, each memory cell with a respective log likelihood value corresponding to the decoder input bin comprising the threshold voltage exhibited by the memory cell. In particular, the processing logic may identify the decoder input bin in which the threshold voltage exhibited by the memory cell falls, and then may utilize the calibrated LLR values computed at operation 440 to determine the LLR value corresponding to the identified bin.

At operation 460, the processing logic may feed, to the LDPC decoder, the log likelihood values computed for the respective memory cells in order to decode the current stage data.

At operation 470, responsive to determining that the current stage data is error-free, the processing logic may return the decoded host data produced by the LDPC decoder; otherwise, the processing logic may initiate the next error handing stage, as described in more detail herein above.

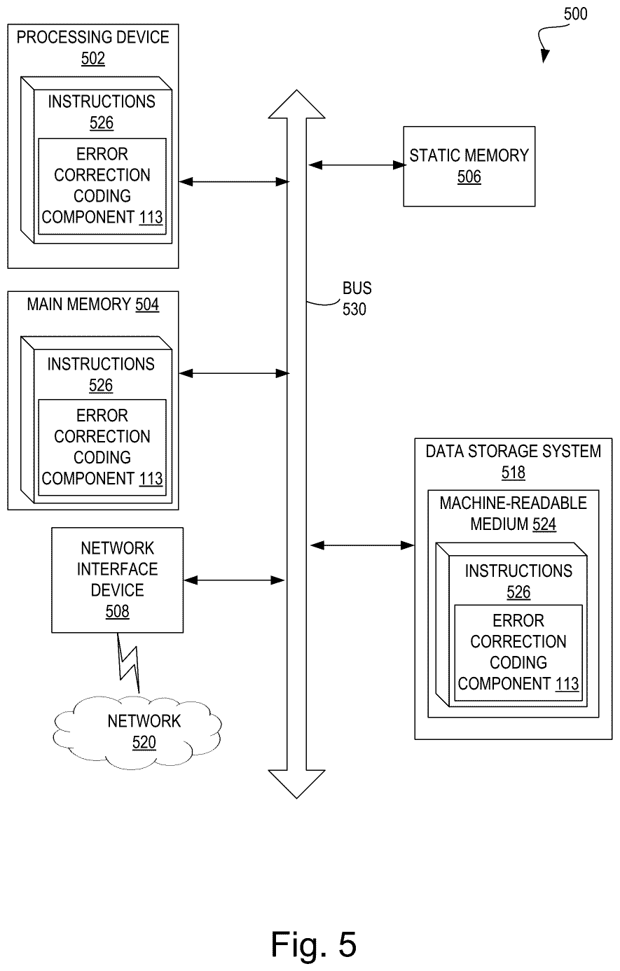

FIG. 5 illustrates an example machine of a computer system 500 within which a set of instructions, for causing the machine to perform any one or more of the methods discussed herein, may be executed. In some implementations, the computer system 500 may correspond to a host system (e.g., the host system 120 of FIG. 1) that includes, is coupled to, or utilizes a memory sub-system (e.g., the memory sub-system 110 of FIG. 1) or may be used to perform the operations of a controller (e.g., to execute an operating system to perform operations corresponding to the ECC component 113 of FIG. 1). In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methods discussed herein.

The example computer system 500 includes a processing device 502, a main memory 504 (e.g., read-only memory (ROM), flash memory, dynamic random access memory (DRAM) such as synchronous DRAM (SDRAM) or RDRAM, etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 may also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 may further include a network interface device 508 to communicate over the network 520.

The data storage system 518 may include a machine-readable storage medium 524 (also known as a computer-readable medium) on which is stored one or more sets of instructions 526 or software embodying any one or more of the methods or functions described herein. The instructions 526 may also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 may correspond to the memory sub-system 110 of FIG. 1.

In one implementation, the instructions 526 include instructions to implement functionality corresponding to an error correction coding component (e.g., the ECC component 113 of FIG. 1). While the machine-readable storage medium 524 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methods of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure may refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus may be specially constructed for the intended purposes, or it may include a general purpose computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems may be used with programs in accordance with the teachings herein, or it may prove convenient to construct a more specialized apparatus to perform the method. The structure for a variety of these systems will appear as set forth in the description below. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, implementations of the disclosure have been described with reference to specific example implementations thereof. It will be evident that various modifications may be made thereto without departing from the broader spirit and scope of implementations of the disclosure as set forth in the following claims. The specification and drawings are, accordingly, to be regarded in an illustrative sense rather than a restrictive sense.

What is claimed is:

1. A system, comprising:
a memory device; and
a processing device, operatively coupled to the memory device, the processing device to:
read, from the memory device, at a current stage of a read error handling sequence, current stage data representing a subset of encoded data stored in a plurality of memory cells of the memory device;
determine, for each decoder input bin of a plurality of decoder input bins, a first number of memory cells having their respective threshold voltages falling into the decoder input bin and further having a first binary value yielded by a previous stage of the read error handling sequence;
determine, for each decoder input bin of the plurality of decoder input bins, a second number of memory cells having their respective threshold voltages falling into the decoder input bin and further having a second binary value yielded by the previous stage of the read error handling sequence;
calibrate, for each decoder input bin of the plurality of decoder input bins, a corresponding likelihood value based on the first number of memory cells associated with the decoder input bin and the second number of memory cells associated with the decoder input bin;
associate each memory cell of the plurality of memory cells with a respective likelihood value corresponding to a decoder input bin comprising a threshold voltage exhibited by the memory cell; and
decode, based on a plurality of likelihood values associated with the plurality of memory cells, the current stage data.

2. The system of claim 1, wherein a likelihood value associated with a particular decoder input bin reflects a probability of a memory cell having its threshold voltage within the particular bin to be decoded as a particular binary value.

3. The system of claim 1, wherein the likelihood value associated with a decoder input bin is a logarithm of the ratio of the first number of memory cells having the first binary value yielded by the previous stage of the read error handling sequence and the second number of memory cells having the second binary value yielded by the previous stage of the read error handling sequence.

4. The system of claim 1, wherein the previous stage read of the error handling sequence exhibits a smallest syndrome weight among syndrome weights of a plurality of stages preceding the current stage in the read error handling sequence.

5. The system of claim 1, wherein decoding the current stage data is performed using a low-density parity-check (LDPC) matrix.

6. The system of claim 1, wherein calibrating, for each decoder input bin of the plurality of decoder input bins, a corresponding likelihood value is performed responsive to determining that a syndrome weight produced by the previous stage falls below a threshold syndrome weight value.

7. The system of claim 1, wherein the processing device is further to:
responsive to determining that a codeword produced by decoding the current stage data comprises one or more errors, performing a next stage of the read error handling sequence.

8. A method, comprising:
reading, from a memory device, at a current stage of a read error handling sequence, current stage data representing a subset of encoded data stored in a plurality of memory cells of the memory device;
determining, for each decoder input bin of a plurality of decoder input bins, a first number of memory cells having their respective threshold voltages falling into the decoder input bin and further having a first binary value yielded by a previous stage of the read error handling sequence;
determine, for each decoder input bin of the plurality of decoder input bins, a second number of memory cells having their respective threshold voltages falling into the decoder input bin and further having a second binary value yielded by the previous stage of the read error handling sequence;
calibrating, for each decoder input bin of the plurality of decoder input bins, a corresponding likelihood value based on the first number of memory cells associated with the decoder input bin and the second number of memory cells associated with the decoder input bin;
associating each memory cell of the plurality of memory cells with a respective likelihood value corresponding to a decoder input bin comprising a threshold voltage exhibited by the memory cell; and
decoding, based on a plurality of likelihood values associated with the plurality of memory cells, the current stage data.

9. The method of claim 8, wherein a likelihood value associated with a particular decoder input bin reflects a probability of a memory cell having its threshold voltage within the particular bin to be decoded as a particular binary value.

10. The method of claim 8, wherein the likelihood value associated with a decoder input bin is a logarithm of the ratio of the first number of memory cells having the first binary value yielded by the previous stage of the read error handling sequence and the second number of memory cells having the second binary value yielded by the previous stage of the read error handling sequence.

11. The method of claim 8, wherein the previous stage read of the error handling sequence exhibits a smallest syndrome weight among syndrome weights of a plurality of stages preceding the current stage in the read error handling sequence.

12. The method of claim 8, wherein decoding the current stage data is performed using a low-density parity-check (LDPC) matrix.

13. The method of claim 8, wherein calibrating, for each decoder input bin of the plurality of decoder input bins, a corresponding likelihood value is performed responsive to determining that a syndrome weight produced by the previous stage falls below a threshold syndrome weight value.

14. The method of claim 8, further comprising:
responsive to determining that a codeword produced by decoding the current stage data comprises one or more errors, performing a next stage of the read error handling sequence.

15. A non-transitory computer-readable storage medium comprising instructions that, when executed by a processing device, cause the processing device to:
read, from the memory device, at a current stage of a read error handling sequence, current stage data representing a subset of encoded data stored in a plurality of memory cells of the memory device;
determine, for each decoder input bin of a plurality of decoder input bins, a first number of memory cells having their respective threshold voltages falling into the decoder input bin and further having a first binary value yielded by a previous stage of the read error handling sequence;
determine, for each decoder input bin of the plurality of decoder input bins, a second number of memory cells having their respective threshold voltages falling into the decoder input bin and further having a second binary value yielded by the previous stage of the read error handling sequence;
calibrate, for each decoder input bin of the plurality of decoder input bins, a corresponding likelihood value based on the first number of memory cells associated with the decoder input bin and the second number of memory cells associated with the decoder input bin;
associate each memory cell of the plurality of memory cells with a respective likelihood value corresponding to a decoder input bin comprising a threshold voltage exhibited by the memory cell; and
decode, based on a plurality of likelihood values associated with the plurality of memory cells, the current stage data.

16. The non-transitory computer-readable storage medium of claim 15, wherein a likelihood value associated with a particular decoder input bin reflects a probability of a memory cell having its threshold voltage within the particular bin to be decoded as a particular binary value.

17. The non-transitory computer-readable storage medium of claim 15, wherein the likelihood value associated with a decoder input bin is a logarithm of the ratio of the first number of memory cells having the first binary value yielded by the previous stage of the read error handling sequence and the second number of memory cells having the second binary value yielded by the previous stage of the read error handling sequence.

18. The non-transitory computer-readable storage medium of claim 15, wherein the previous stage read of the error handling sequence exhibits a smallest syndrome weight among syndrome weights of a plurality of stages preceding the current stage in the read error handling sequence.

19. The non-transitory computer-readable storage medium of claim 15, wherein decoding the current stage data is performed using a low-density parity-check (LDPC) matrix.

20. The non-transitory computer-readable storage medium of claim 15, wherein calibrating, for each decoder input bin of the plurality of decoder input bins, a corresponding likelihood value is performed responsive to determining that a syndrome weight produced by the previous stage falls below a threshold syndrome weight value.
